(19) United States
(12) Patent Application Publication
(10) Pub. No.: US 2011/0017277 A1
(43) Pub. Date: Jan. 27, 2011

(54) Concentration photovoltaic and heating apparatus

(76) Inventors: Kun-Fang Huang, Taichung City (TW); Tsair-Rong Chen, Changhua City (TW); Liang-Hsing Lai, Taichung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/458,805

(22) Filed: Jul. 23, 2009

(51) Int. Cl. H02N 6/00; H01L 31/00

(52) U.S. Cl. 136/248; 136/259

(57) ABSTRACT

A concentration photovoltaic and heating apparatus including a printed circuit board (PCB), a power generating module, a heat conducting plate and a heat conducting pipe is provided. The power generating module includes a solar chip and a Fresnel lens. The solar chip is mounted on the PCB and configured for transforming light energy into electricity. The Fresnel lens is disposed over the solar chip and configured for focusing sunlight on the solar chip. The heat conducting plate carries the PCB. The heat conducting pipe is connected to the heat conducting plate. A fluid flowing in the heat conducting pipe is configured for being heated by a heat generated by the solar chip through the heat conducting plate.

### BACKGROUND OF THE INVENTION

1. Field of the Invention

The present invention relates to a solar power generating apparatus, particularly to a concentration photovoltaic and heating apparatus using heat generated during transforming sunlight into electricity to heat up fluid.

2. Description of the Prior Art

The requirement for alternative energy has now increased with the persistent shortage of petroleum energy and uprising of the environmental protection awareness. Particularly, the solar energy has become promising in alternative energy research and development due to its desiring properties, such as great availability, cleanness, and substantially unexhausted usage.

Common applications for solar energy include solar power generating apparatus and solar water-heater for now. However, the solar power generating apparatus has a very high manufacturing cost with relatively low photoelectric efficiency and the heat generated by electricity generation is dissipated and would not be reused. Therefore, the solar power generating. apparatus does not have high economical performance. Also, the solar water-heating using solar heat has relatively efficiency for light-heat conversion since most of sunlight would be reflected and refracted and therefore be wasted. This means the solar applications at present have relatively low over-all utilizing efficiency for solar energy, and it is now a current goal to increasing the over-all utilizing efficiency for solar energy.

### SUMMARY OF THE INVENTION

The present invention is directed to a concentration photovoltaic and heating apparatus with higher over-all utilizing efficiency for solar energy.

According to an embodiment, a concentration photovoltaic and heating apparatus including a printed circuit board (PCB), a power generating module, a heat conducting plate and a heat conducting pipe is provided. The power generating module includes a solar chip and a Fresnel lens. The solar chip is mounted on the PCB and configured for transforming light energy into electricity. The Fresnel lens is disposed over the solar chip and configured for focusing sunlight on the solar chip. The heat conducting plate carries the PCB. The heat conducting pipe is connected to the heat conducting plate. A fluid flowing in the heat conducting pipe is configured for being heated by a heat generated by the solar chip through the heat conducting plate.

In one embodiment, a plurality of solar chips are provided, configured on the PCB in an array, and electrically interconnected via the PCB, and the Fresnel lens is configured for focusing the sunlight onto the solar chip.

In one embodiment, a plurality of power generating modules are provided and the solar chips thereof are electrically interconnected via the PCB.

In one embodiment, a plurality of solar chips are provided in each of the power generating modules, configured on the PCB in an array, and electrically interconnected via the PCB, and the Fresnel lens is configured for focusing the sunlight onto the solar chip.

In one embodiment, the concentration photovoltaic and heating apparatus further includes a tank connected with one end of the heat conducting pipe and configured for storing the heated fluid.

In one embodiment, the heat conducting pipes passes through the heat conducting plate.

In one embodiment, the heat conducting pipe includes a plurality of branch pipes passing through the heat conducting plate and interconnected in series or in parallel.

In one embodiment, the PCB is made of aluminum, ceramics, graphite, or combinations thereof.

In one embodiment, the heat conducting plate is made of copper, aluminum, stainless steel, or combinations thereof.

In one embodiment, the heat conducting pipe is made of copper, aluminum, stainless steel, or combinations thereof.

In one embodiment, the fluid is water.

According to the above-mentioned, the present invention converts light into electricity by using a solar chip, heats up the fluid circulating in the heat conducting pipe through the heat conducting plate with the heat generated by the solar chip for further usage, and hence has higher over-all utilizing efficiency for solar energy.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a structural schematic diagram illustrating a concentration photovoltaic and heating apparatus according to an embodiment of the present invention;

FIG. 2A is a top view diagram illustrating the heat conducting pipes passing through the heat conducting plate according to one embodiment of the present invention;

FIG. 2B is a top view diagram illustrating the heat conducting pipes passing through the heat conducting plate according to another embodiment of the present invention;

FIG. 3 is a structural schematic diagram illustrating a concentration photovoltaic and heating apparatus according to another embodiment of the present invention; and

FIG. 4 is a structural schematic diagram illustrating a concentration photovoltaic and heating apparatus according to yet another embodiment of the present invention.

### DESCRIPTION OF THE PREFERRED EMBODIMENT

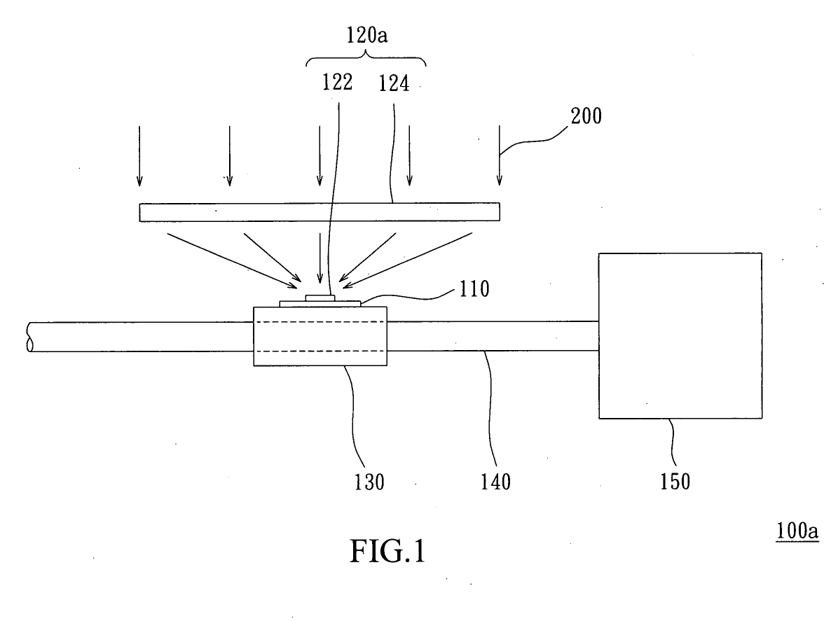

FIG. 1 is a structural schematic diagram illustrating a concentration photovoltaic and heating apparatus according to an embodiment of the present invention. Referring to FIG. 1, the concentration photovoltaic and heating apparatus 100a includes a printed circuit board (PCB) 110, a power generating module 120a, a heat conducting plate 130, and a heat conducting pipe 140, wherein the power generating module 120a includes a solar chip 122 and a Fresnel lens 124. The solar chip 122 is mounted on the PCB 110 and the Fresnel lens 124 is disposed over solar chip 122 and configured for focusing sunlight 200 onto the solar chip 122. In addition, the heat conducting plate 130 carries the PCB 110, the heat conducting pipe 140 is connected to the heat conducting plate 130, and the heat conducting plate 130 and heat conducting pipe 140 are both made of copper. Therefore, fluid circulating in the heat conducting pipe 140 may be heated by heat generated by solar chip 122 through heat conducting plate 130.

To be specific, the sunlight 200 is focused onto the solar chip 122 via the Fresnel lens 124 and partially transformed into electricity by the solar chip 122, and the rest of the sunlight 200 is converted to heat, which heat up the solar chip 122. Water may be then infused into heat conducting pipe 140 via one end for heat dissipation of solar chip 122. The heated water may efflux through the other end of the heat conducting pipe 140 for usage or flow into a tank 150 via the other end of the heat conducting pipe 140 for storage. Accordingly, the concentration photovoltaic and heating apparatus 100a may generate not only electricity using sunlight 200 but also heat for water-heater while generating electricity. The present invention hence has higher over-all utilizing efficiency for solar energy while comparing to conventional techniques.

In this embodiment, it is noted that the PCB 110 may be made of aluminum, and the heat conducting pipe 140 may pass through the heat conducting plate 130 and couple to the heat conducting plate 130 in a compact manner so that the heat on the solar chip 122 may be rapidly conducted to the fluid in the heat conducting pipe 140 through the PCB 110, heat conducting plate 130, and heat conducting pipe 140. However, the PCB 110 may be made of aluminum, ceramics, graphite, or combinations thereof in other embodiments. In addition, the heat conducting plate 130 and heat conducting pipe 140 may be made of copper, aluminum, stainless steel, combinations thereof, or any other conductive materials. The heat conducting plate 130 and heat conducting pipe 140 may be made of different materials. Furthermore, the fluid in the heat conducting pipe 140 may be, without limitation to, water or any other fluid to be heated for usage.

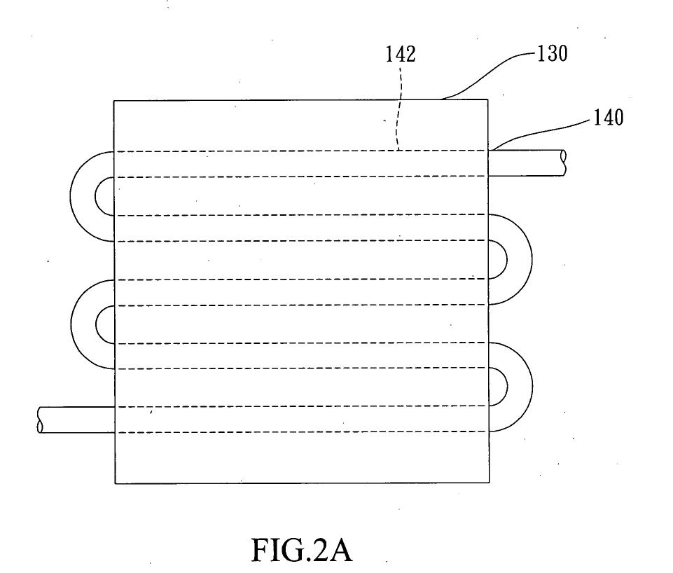

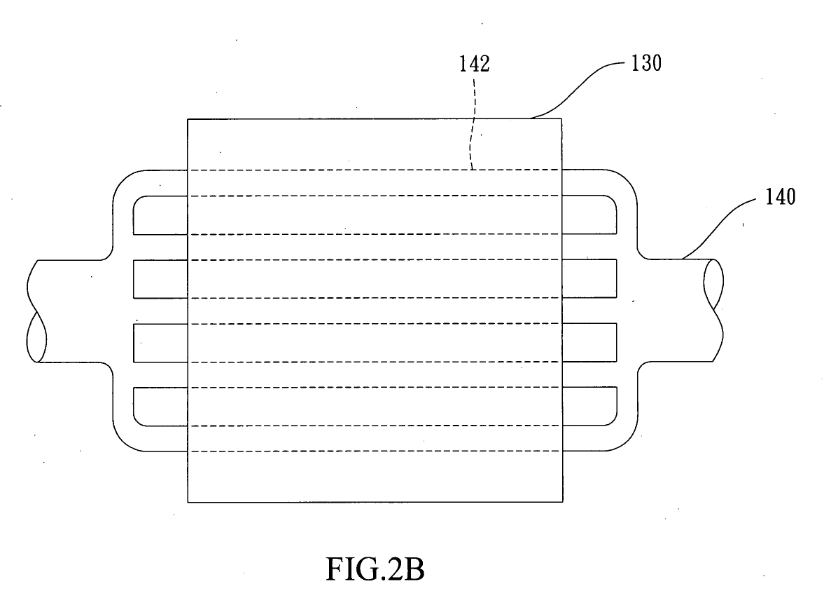

FIG. 2A and FIG. 2B are top view diagrams respectively illustrating heat conducting pipes passing through the heat conducting plate. As illustrated in FIG. 1, the heat conducting pipe 140 of the present invention may be a straight pipe passing through the heat conducting plate 130 directly. In addition, a portion of heat conducting pipe 140 that connects to the heat conducting plate 130 may include a plurality of branch pipes 142. These branch pipes 142 may pass through the heat conducting plate 130 in a compact manner and be interconnected in series (as illustrated in FIG. 2A) or in parallel (as illustrated in FIG. 2B) for larger heat conducting area between the heat conducting plate 130 and heat conducting pipe 140.

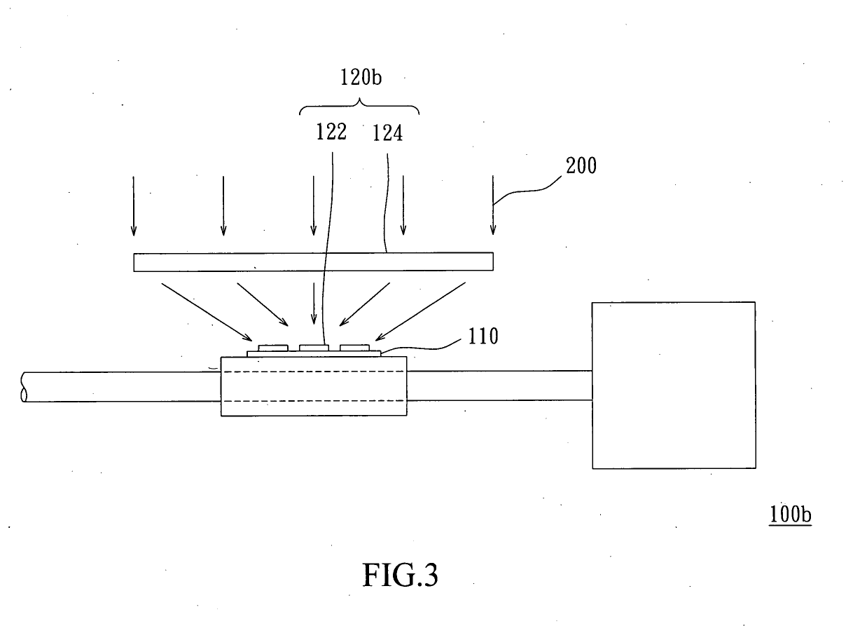

FIG. 3 is a structural schematic diagram illustrating a concentration photovoltaic and heating apparatus according to another embodiment of the present invention. The concentration photovoltaic and heating apparatus 100b illustrated in FIG. 3 differs from the concentration photovoltaic and heating apparatus 100a illustrated in FIG. 1 in the number of the solar chip 122. This means the power generating module 120b of the concentration photovoltaic and heating apparatus 100b may include a plurality of solar chips 122. These solar chips 122 may be configured on the PCB 110 in an array, and electrically interconnected via the PCB 110, and the Fresnel lens 124 may be configured for focusing the sunlight 220 onto the solar chips 122. Accordingly, the concentration photovoltaic and heating apparatus 100b may generate not only electricity using sunlight 200 but also heat for water-heater while generating electricity.

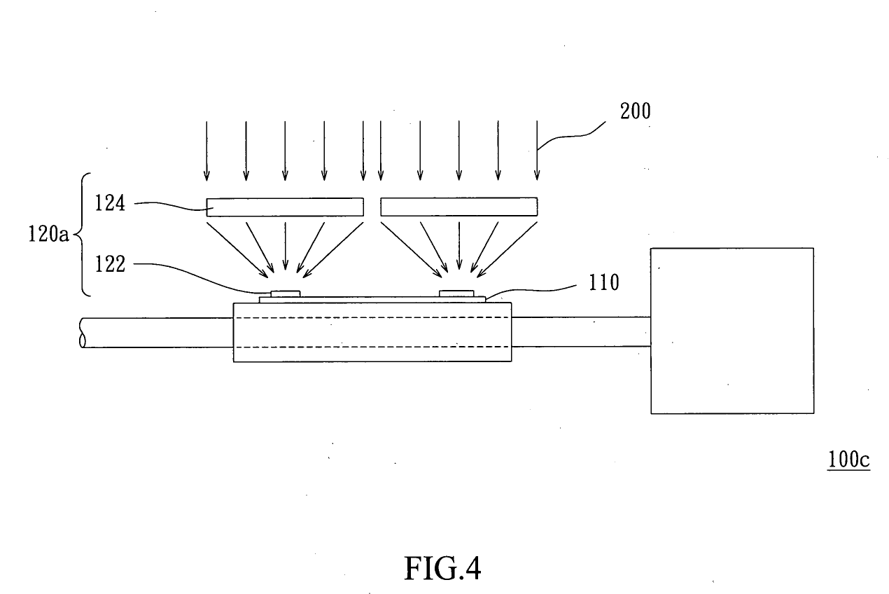

FIG. 4 is a structural schematic diagram illustrating a concentration photovoltaic and heating apparatus according to yet another embodiment of the present invention. The concentration photovoltaic and heating apparatus 100c illustrated in FIG. 4 differs from the concentration photovoltaic and heating apparatus 100a illustrated in FIG. 1 in the number of power generating module 120a. In this embodiment, the solar chips 122 of each power generating module 120a may be interconnected via the PCB 110 in series or in parallel based on usage requirement. Accordingly, the concentration photovoltaic and heating apparatus 100c may generate not only electricity using sunlight 200 but also heat for water-heater while generating electricity.

In addition, in other non-schematic embodiments, the concentration photovoltaic and heating apparatus may include a plurality of power generating modules, and each power generating module may further include a plurality of solar chips. Here, the Fresnel lens of each power generating module may be configured for focusing sunlight onto the multiple solar chips of the same power generating module. Also, the multiple solar chips of the same power generating module may be interconnected via the PCB 110 in series or in parallel based on usage requirement.

To sum up, the present invention transforms light into electricity by using a solar chip and heats up the fluid circulating in the heat conducting pipe through the heat conducting plate with the heat generated by the solar chip for further usage. The present invention hence has higher over-all utilizing efficiency for solar energy while comparing to conventional techniques. Also, the whole generating capacity and circulating efficiency fluid in the concentration photovoltaic and heating apparatus may be enhanced by increasing the amount of power generating modules or solar chip based on usage requirement. Furthermore, a portion of heat conducting pipe that connects to the heat conducting plate may include a plurality of branch pipes for larger heat conducting area between the heat conducting plate and heat conducting pipe.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A concentration photovoltaic and heating apparatus, comprising:
a printed circuit board;
at least a power generating module comprising:
at least a solar chip mounted on the printed circuit board and configured for transforming light energy into electricity; and
a Fresnel lens disposed over the solar chip and configured for focusing a sunlight onto the solar chip;
a heat conducting plate carrying the printed circuit board; and
at least a heat conducting pipe connected to the heat conducting plate and carrying a fluid configured for being heated by a heat generated by the solar chip through the heat conducting plate.

2. The concentration photovoltaic and heating apparatus as claimed in claim 1, wherein a plurality of solar chips are provided, configured on the printed circuit board in an array, and electrically interconnected via the printed circuit board, and the Fresnel lens is configured for focusing the sunlight onto the solar chip.

3. The concentration photovoltaic and heating apparatus as claimed in claim 1, wherein a plurality of power generating modules are provided and the solar chips thereof are electrically interconnected via the printed circuit board.

4. The concentration photovoltaic and heating apparatus as claimed in claim 3, wherein a plurality of solar chips are provided in each of the power generating modules, configured on the printed circuit board in an array, and electrically interconnected via the printed circuit board, and the Fresnel lens is configured for focusing the sunlight onto the solar chip.

5. The concentration photovoltaic and heating apparatus as claimed in claim 1, further comprising:
a tank connected with one end of the heat conducting pipe and configured for storing the heated fluid.

6. The concentration photovoltaic and heating apparatus as claimed in claim 1, wherein the heat conducting pipe passes through the heat conducting plate.

7. The concentration photovoltaic and heating apparatus as claimed in claim 1, wherein the heat conducting pipe includes a plurality of branch pipes passing through the heat conducting plate and interconnected in series or in parallel.

8. The concentration photovoltaic and heating apparatus as claimed in claim 1, wherein the printed circuit board is made of aluminum, ceramics, graphite, or combinations thereof.

9. The concentration photovoltaic and heating apparatus as claimed in claim 1, wherein the heat conducting plate is made of copper, aluminum, stainless steel, or combinations thereof.

10. The concentration photovoltaic and heating apparatus as claimed in claim 1, wherein the heat conducting pipe is made of copper, aluminum, stainless steel, or combinations thereof.

11. The concentration photovoltaic and heating apparatus as claimed in claim 1, wherein the fluid is water.
